(19) United States
(12) Patent Application Publication
(10) Pub. No.: US 2010/0194419 A1
(43) Pub. Date: Aug. 5, 2010

(54) MULTI-CONTACT PROBE ASSEMBLY

(76) Inventors: Edward K. Chan, Diamond Bar, CA (US); Robert H. Okita, Gardena, CA (US)

Correspondence Address: Timothy K. Klintworth;EVAN LAW GROUP LLC, Suite 625, 600 W. Jackson Blvd., Chicago, IL, 60661, US

(21) Appl. No.: 12/366,349

(22) Filed: Feb. 5, 2009

(51) Int. Cl. G01R 1/067; G01R 31/02

(52) U.S. Cl. 324/761

(57) ABSTRACT

A multi-contact probe assembly may include a housing, a plurality of probe members, a plurality of spring members, and a plurality of electrical connectors. The housing may comprise a plurality of shafts in a pre-determined pattern. The plurality of probe members may be partially and moveably disposed within the plurality of shafts. The plurality of spring members may be disposed within the plurality of shafts spring-loading the probe members to partially and moveably extend beyond the plurality of shafts out of the housing in the pre-determined pattern. The plurality of electrical connectors may extend into the plurality of shafts for communicating signals from electrical testing equipment to the probe members. The pre-determined pattern may be substantially identical to a pattern of contacts on a circuit board being tested by the multi-contact probe assembly. In such manner, a circuit board which has a pattern of contacts that is substantially identical to the pre-determined pattern of probe members may be tested.

### STATEMENT REGARDING NASA CONTRACT

The disclosure described herein was made in the performance of work under NASA Contract No. NNG08DA00C and is subject to the provisions of Section 305 of the National Aeronautics and Space Act of 1958 (72 Stat. 435: 42 U.S.C. 2457).

### BACKGROUND OF THE DISCLOSURE

Some conventional apparatus and/or methods for testing circuit boards utilize a single probe to individually make electrical contacts on the circuit board one at a time. This may take substantial time, increase cost, and be inefficient. Other conventional apparatus and/or methods utilize elaborate and/or expensive test fixtures which must be mounted to the circuit board being tested. This again may take substantial time, increase cost, and be inefficient. Other conventional apparatus and/or methods may experience varying types of problems.

An apparatus and method is needed which may solve one or more problems of one or more of the conventional apparatus and/or methods.

### SUMMARY OF THE DISCLOSURE

In one aspect of the disclosure, a multi-contact probe assembly is disclosed. The multi-contact assembly may include a housing, a plurality of probe members, a plurality of spring members, and a plurality of electrical connectors. The housing may comprise a plurality of shafts in a pre-determined pattern. The plurality of probe members may be partially and moveably disposed within the plurality of shafts. The plurality of spring members may be disposed within the plurality of shafts spring-loading the probe members to partially and moveably extend beyond the plurality of shafts out of the housing in the pre-determined pattern. The plurality of electrical connectors may extend into the plurality of shafts for communicating signals to the probe members.

In another aspect of the disclosure, a method of testing a circuit board may be disclosed. In one step, a multi-contact probe assembly may be provided. The multi-contact probe assembly may comprise a housing having a plurality of shafts in a pre-determined pattern, and a plurality of probe members moveably disposed partially within the shafts and biased to partially extend beyond the plurality of shafts out of the housing in the pre-determined pattern. In another step, a plurality of contacts on a circuit board may be contacted with the plurality of probe members. The plurality of contacts may be in a substantially identical pattern as the pre-determined pattern. In an additional step, the circuit board may be tested using the probe members.

These and other features, aspects and advantages of the disclosure will become better understood with reference to the following drawings, description and claims.

### BRIEF DESCRIPTION OF THE DRAWINGS

FIG. 1 is a perspective view of a multi-contact probe assembly;

FIG. 2 is a front view of the multi-contact probe assembly of FIG. 1;

FIG. 3 is a cross-section view along line 3-3 of the multi-contact probe assembly of FIG. 2;

FIG. 4 is a front view of the multi-contact probe assembly of FIG. 2 showing a representative shaft of the probe assembly;

FIG. 5 is a perspective view showing the multi-contact probe assembly of FIG. 1 aligned into position to be connected to a circuit board;

FIG. 5A is a perspective view showing the multi-contact probe assembly of FIG. 5 connected to the circuit board;

FIG. 5B is a perspective view showing an alternative embodiment of a circuit board holding fixture mounted to a circuit board and multi-probe assembly;

FIG. 6 shows an alternative pre-determined pattern which may be utilized for the probes of the multi-contact probe assembly of FIG. 1;

FIG. 7 shows another alternative pre-determined pattern which may be utilized for the probes of the multi-contact probe assembly of FIG. 1;

FIG. 8 shows still another alternative pre-determined pattern which may be utilized for the probes of the multi-contact probe assembly of FIG. 1;

FIG. 9 shows yet another alternative pre-determined pattern which may be utilized for the probes of the multi-contact probe assembly of FIG. 1;

FIG. 10 is a flowchart of one embodiment of a method of testing a circuit board.

### DETAILED DESCRIPTION OF THE DISCLOSURE

The following detailed description is of the best currently contemplated modes of carrying out the disclosure. The description is not to be taken in a limiting sense, but is made merely for the purpose of illustrating the general principles of the disclosure, since the scope of the disclosure is best defined by the appended claims.

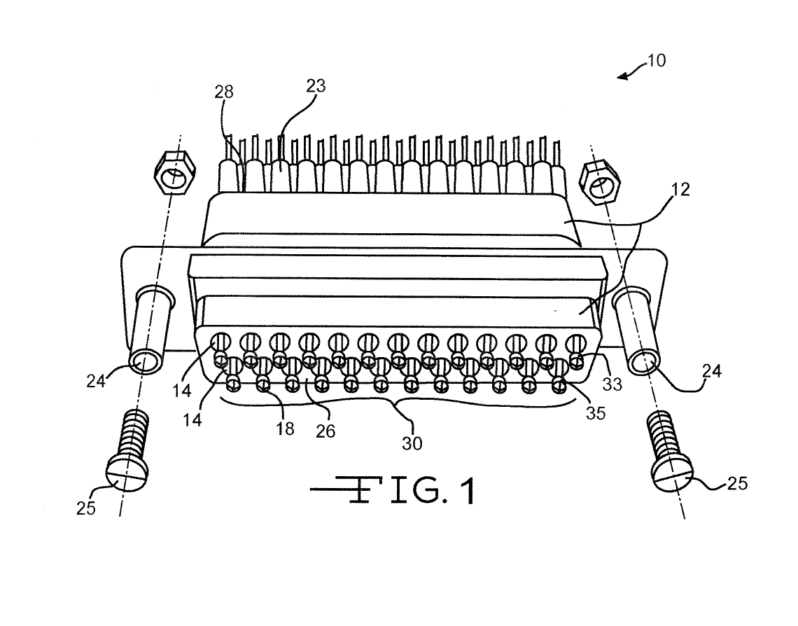

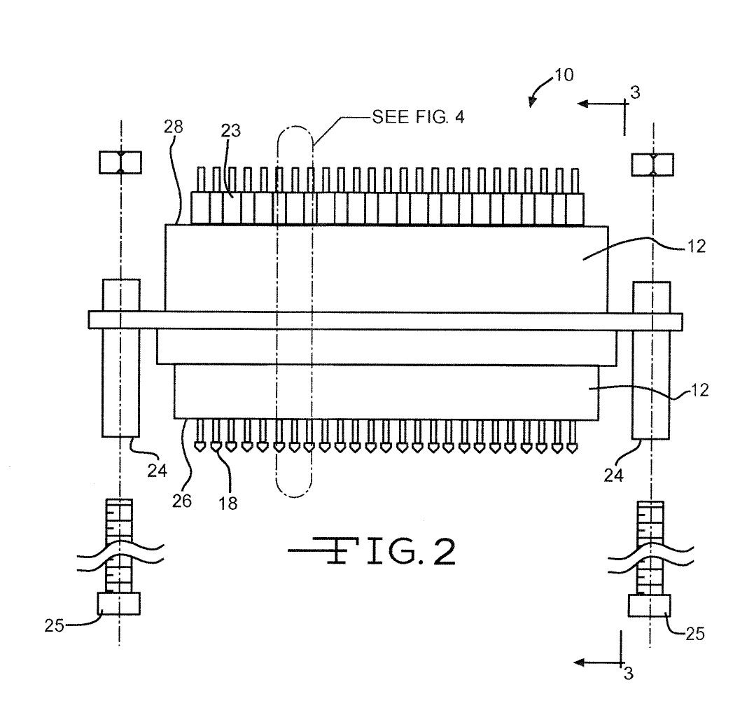

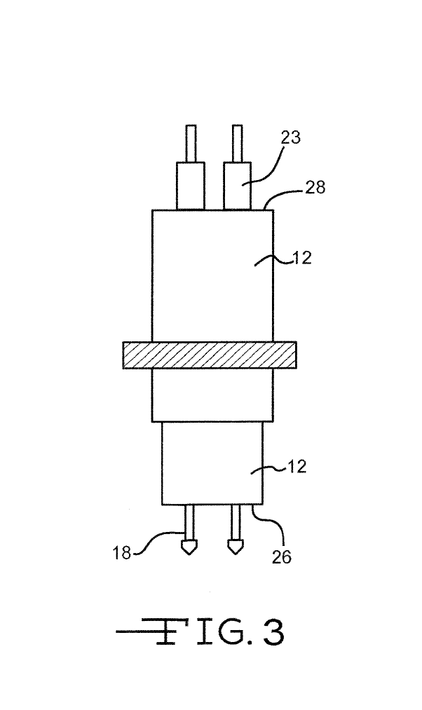

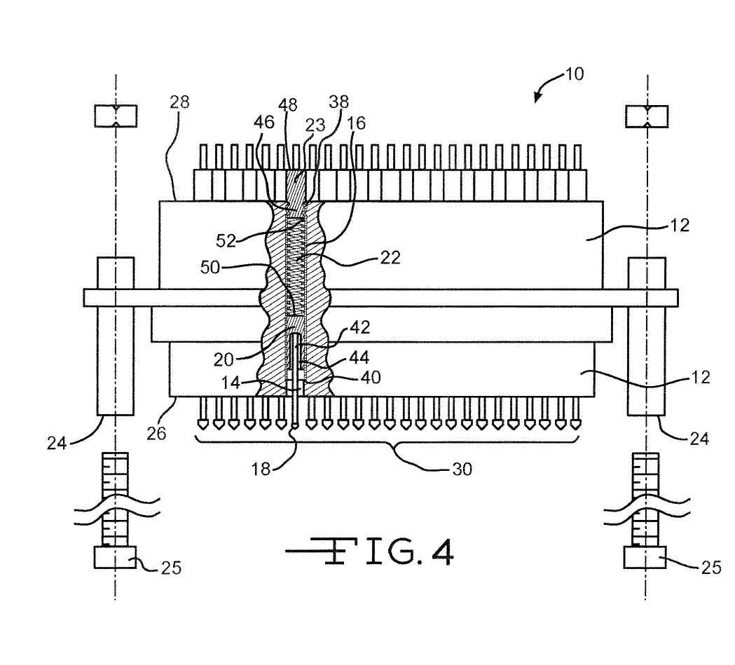

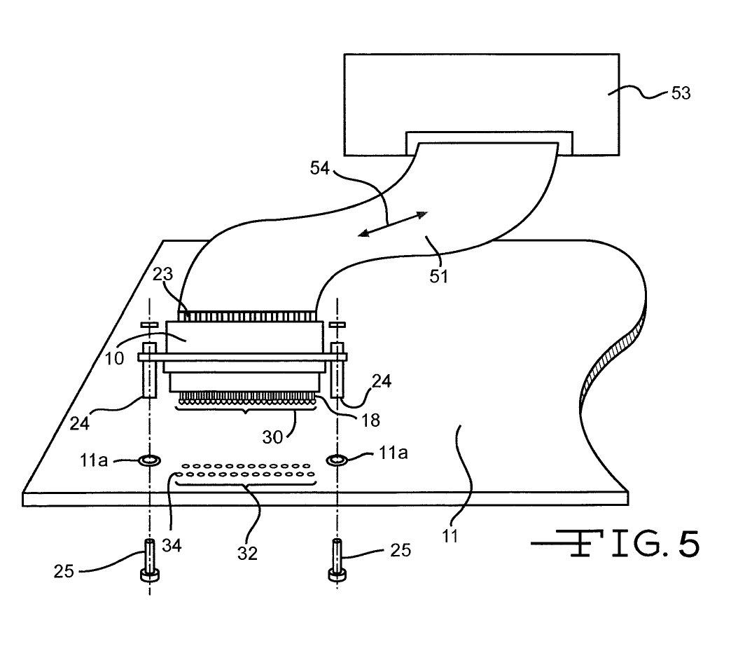

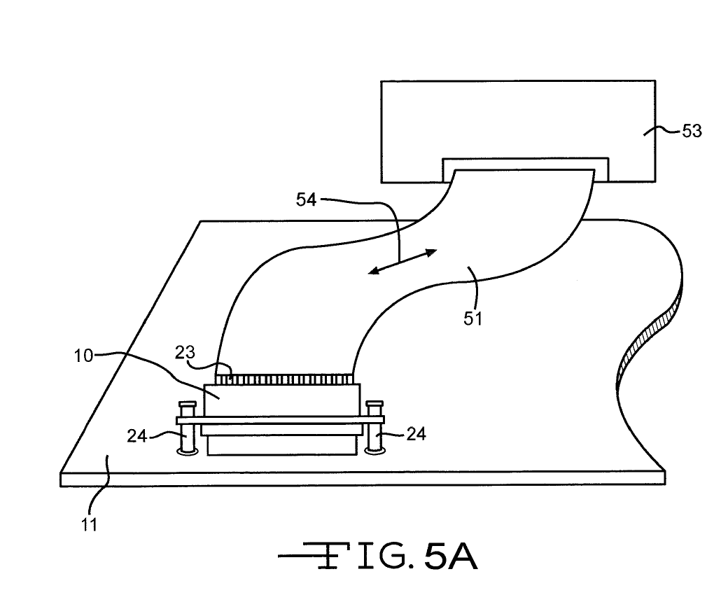

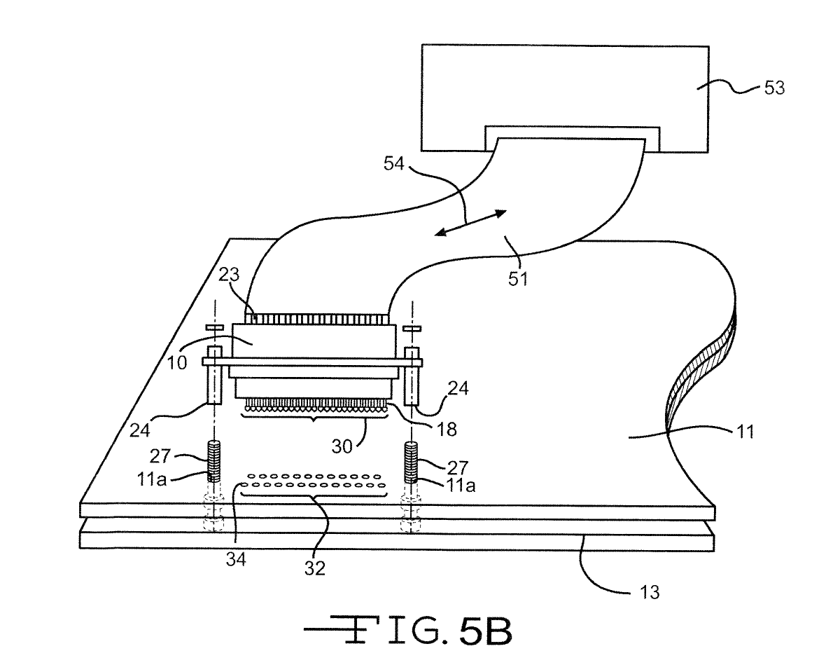

FIG. 1 is a perspective view of a multi-contact probe assembly 10. FIG. 2 is a front view of the multi-contact probe assembly 10 of FIG. 1. FIG. 3 is a cross-section view along line 3-3 of the multi-contact probe assembly 10 of FIG. 2. FIG. 4 is a front view of the multi-contact probe assembly 10 of FIG. 2 showing a partial cross-sectional view to illustrate a representative shaft 14 of the probe assembly 10. Although only one representative cross-section of a shaft 10 is shown in FIG. 4, all of the shafts 10 may be identical and have identical internal components as shown in FIG. 4. FIG. 5 is a perspective view showing the multi-contact probe assembly 10 of FIG. 1 aligned into position to be connected to a circuit board 11. FIG. 5A is a perspective view showing the multi-contact probe assembly 10 of FIG. 5 connected to the circuit board 11. As shown in FIGS. 1-5A, the multi-contact probe assembly 10 may comprise a housing 12, a plurality of shafts 14, a plurality of conductive barrel members 16 disposed within the shafts 14 (a representative conductive barrel member 16 disposed within one of the shafts 14 is shown in FIG. 4), a plurality of probe members 18, a plurality of probe connector members 20 disposed within the shafts 14 (a representative probe connector member 20 disposed within one of the shafts 14 is shown in FIG. 4), a plurality of spring members 22 disposed within the shafts 14 (a representative spring member 22 disposed within one of the shafts 14 is shown in FIG. 4), a plurality of electrical connectors 23, and at least one fastener receptacle 24 for a fastener 25. The multi-contact probe assembly 10 may comprise a D-connector, and/or another type of connector assembly. The multi-contact probe assembly 10 may be suitable for use in manual and/or automated test equipment.

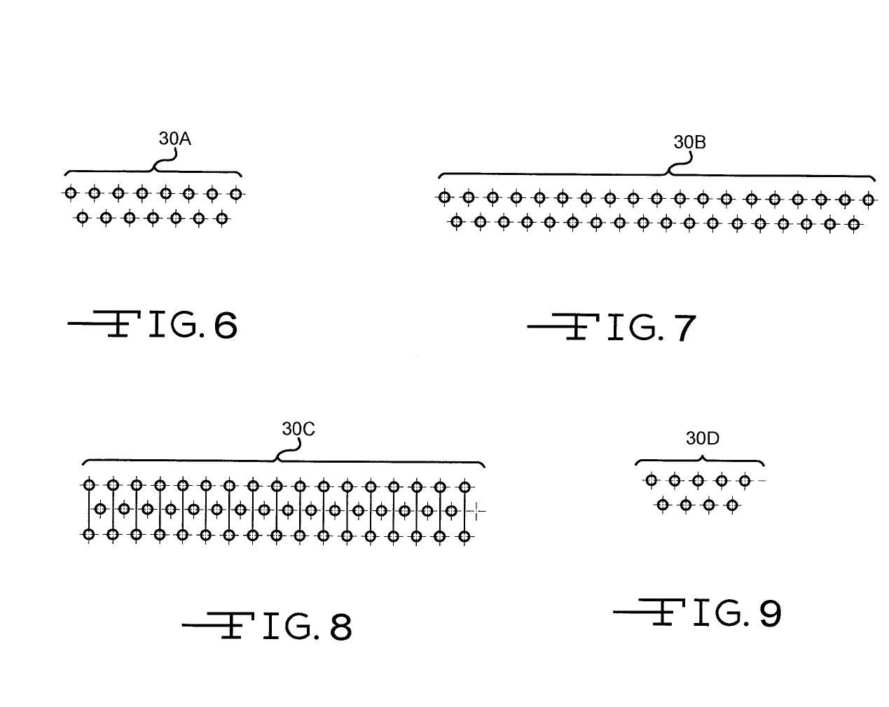

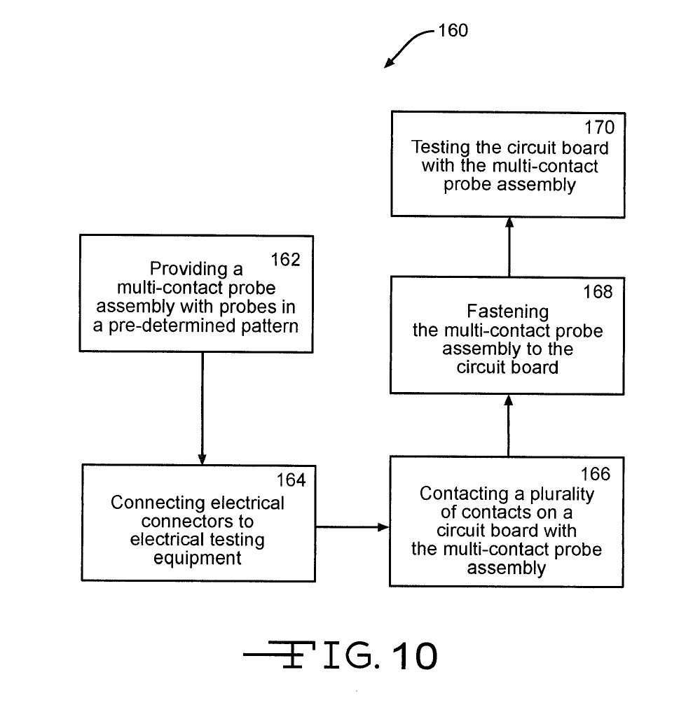

The housing 12 may be made of plastic, or other types of materials. The plurality of shafts 14 may extend from one end 26 to another end 28 of the housing 12. The plurality of shafts 14 may be in a pre-determined pattern 30. As shown in FIG. 5, the pre-determined pattern 30 may be substantially identical to a standardized pattern 32 of contacts 34 on the circuit board 11 being tested by the multi-contact probe assembly 10. The pre-determined pattern 30 may comprise multiple rows 33 and 35 of shafts 14. Row 33 may have thirteen shafts and row 35 may have twelve shafts. The rows 33 and 35 may be parallel. The rows 33 and 35 may comprise a varying number of shafts 14. In other embodiments, the pre-determined pattern 30 may vary to substantially mimic another pattern 32 of contacts 34 on a circuit board 11. FIGS. 6-9 show varying representative pre-determined patterns 30A, 30B, 30C, and 30D which may be used for the shafts 14 and probes 18 which may be utilized in the multi-contact probe assembly 10.

The plurality of conductive barrel members 16 may be cylindrical, and may be fixedly disposed within the plurality of shafts 14. The conductive barrel members 16 may be fixedly secured within the shafts 14 using adhesives, press-fits, and/or through other devices or processes. The plurality of conductive barrel members 16 may be made of metal or other conductive materials. One end 38 of each conductive barrel member 16 may be aligned with the end 28 of the housing 12. The other end 40 of each conductive barrel member 16 may be spaced apart from end 26 of the housing 12.

The plurality of probe members 18 may comprise electrical testing probe members for testing contacts 34 of a circuit board 11 as shown in FIG. 5. The plurality of probe members 18 may be fixedly attached to the probe connector members 20 with an end 42 of each probe member 18 disposed within a cavity 44 of each probe connector member 20. The end 42 of each probe member 18 may be fixed secured within the cavity 44 of each probe connector member 20 using adhesives, press-fits, and/or through other devices or processes. The probe connector members 20 may be cylindrical and may be moveably and/or slideably disposed, along with the attached probe members 18, within the conductive barrel members 16. The end 40 of each conductive barrel member 16 may be crimped to prevent the probe connector members 20 and the attached probe members 18 from extending beyond the end 40 of each conductive barrel member 16. When the probe connector members 20 are disposed at the end 40 of each conductive barrel member 16, the attached probe members 18 may partially extend beyond the end 26 of the housing 12 with the plurality of probe members 18 in the pre-determined pattern 30 of the shafts 14.

The electrical connectors 23 may be attached to the end 38 of each conductive barrel member 16. The electrical connectors 23 may be made of a conductive material, a metal, and/or another type of material. One end 46 of each electrical connector 23 may partially extend into the conductive barrel members 16, and another end 48 of each electrical connector 23 may partially extend past the end 28 of the housing 12. The end 38 of each conductive barrel member 16 may be crimped against the electrical connectors 23 to fixedly secure the electrical connectors 23 in place relative to the conductive barrel members 16. The electrical connectors 23 may be soldered to the conductive barrel members 16.

The spring members 22 may be disposed within the barrel members 16. The spring members 22 may be made of a metal, a conductive material, and/or another type of material. One end 50 of each spring member 22 may be disposed against a separate moveable probe connector member 20, and another end 52 of each spring member may be disposed against a separate fixed electrical connector 23. In such manner, the spring members 22 may bias the moveable probe connector members 20 and attached probe members 18 towards end 40 of each conductive barrel member 16. In other embodiments, the multi-contact probe assembly 10 may utilize varying shaped, sized, and type of components in varying configurations.

As shown in FIGS. 5 and 5A, the multi-probe assembly 10 may be attached to the circuit board 11 by inserting fasteners 25 through holes 11a of the circuit board 11 into the fastener receptacles 24. The fasteners 25 may comprise screws and/or other fastening devices. One or more cables 51 extending from electrical testing equipment 53 may be attached to the electrical connectors 23. The probe members 18 in the pre-determined pattern 30 may be simultaneously disposed in contact with the contacts 34 on the circuit board 11 in pattern 32 which may be substantially identical to pre-determined pattern 30. Electrical signals 54 may be communicated between the electrical testing equipment 53 and the probe members 18. The electrical signals 54 may be transmitted and/or received between the electrical testing equipment 53, the cables 51, the electrical connectors 23, the conductive barrel members 16, the probe members 18, and the contacts 34 of the circuit board 11. In such manner, all of the contacts 34 of the circuit board 11 in the pattern 32 may be simultaneously tested using the probe members 18 of the multi-probe assembly 10 in the pre-determined pattern 30. FIG. 5B is a perspective view showing an alternative embodiment of a circuit board holding fixture 13 having built in threaded mounting bosses 27 for mounting through the holes 11a of the circuit board 11 into the receptacles 24 of the multi-probe assembly 10.

FIG. 10 is a flowchart of one embodiment of a method 160 of testing a circuit board 11. In step 162, a multi-contact probe assembly 10 may be provided. The multi-contact probe assembly 10 may comprise a housing 12 having a plurality of shafts 14 in a pre-determined pattern 30. A plurality of probe members 18 may be moveably disposed partially within the shafts 14. The probe members 18 may be biased to partially extend beyond the plurality of shafts 14 out of the housing 12 with a plurality of spring members 22. The plurality of probe members 18 may be biased to partially extend beyond the plurality of shafts 14 out of the housing 12 in the pre-determined pattern 30. The pre-determined pattern 30 may comprise multiple rows 33 and 35 of shafts 14, multiple rows 33 and 35 of shafts 14 comprising a different number of shafts 14, multiple rows 33 and 35 of parallel shafts 14, and/or be in varying patterns. In other embodiments, the multi-contact probe assembly 10 may comprise any of the embodiments disclosed in this disclosure.

In step 164, a plurality of electrical connectors 23 extending into the plurality of shafts 14 may be connected, using at least one cable 51, to electrical testing equipment 53. In step 166, a plurality of contacts 34 on the circuit board 11 may be contacted with the plurality of probe members 18. The plurality of contacts 34 may be in a substantially identical pattern 32 as the pre-determined pattern 30. In step 168, at least one fastener 25 may be inserted into the fastener receptacle(s) 24 of the multi-contact probe assembly 10 in order to attach the assembly 10 to the circuit board 11. In step 170, the plurality of contacts 34 of the circuit board 11 may be simultaneously tested using the probe members 18. Step 170 may comprise communicating 54 signals between the electrical testing equipment 53 and the probe members 18. In other embodiments, one or more steps of the method 160 may be modified or eliminated, and/or other steps may be added.

One or more embodiments of the disclosure may allow for a circuit board 11 to be tested, using a multi-contact probe assembly 10 having spring-loaded probe members 18 in a pre-determined pattern 30, in a reduced amount of time without requiring the need for a special fixture to be manufactured, and with a minimal footprint thereby reducing the risk of damage to the circuit board 10. The spring-loaded probe members 18 may expediently engage and disengage contacts 34 on the circuit board 11 which are in a pattern 32 substantially identical to the pre-determined pattern 30. This may save cost and/or be more efficient than one or more of the conventional apparatus and/or methods. Further, the multi-contact probe assembly 10 may be used in manual and/or automated equipment.

It should be understood, of course, that the foregoing relates to exemplary embodiments of the disclosure and that modifications may be made without departing from the spirit and scope of the disclosure as set forth in the following claims.

We claim:

1. A multi-contact probe assembly comprising:
a housing comprising a plurality of shafts in a pre-determined pattern;
a plurality of probe members partially and moveably disposed within the plurality of shafts;
a plurality of spring members disposed within the plurality of shafts spring-loading the probe members to partially and moveably extend beyond the plurality of shafts out of the housing in the pre-determined pattern; and
a plurality of electrical connectors extending into the plurality of shafts for communicating signals to the probe members.

2. The multi-contact probe assembly of claim 1 wherein at least one cable is connected between the plurality of electrical connectors and electrical testing equipment.

3. The multi-contact probe assembly of claim 1 wherein the pre-determined pattern comprises multiple rows of shafts.

4. The multi-contact probe assembly of claim 3 wherein at least one of: the multiple rows are parallel; and at least two of the rows comprise different numbers of shafts.

5. The multi-contact probe assembly of claim 1 wherein the pre-determined pattern is substantially identical to a pattern of contacts on a circuit board.

6. The multi-contact probe assembly of claim 1 wherein the multi-contact probe assembly is a D-connector assembly.

7. The multi-contact probe assembly of claim 1 further comprising a plurality of conductive barrel members disposed within the plurality of shafts, wherein the plurality of spring members are disposed within the plurality of conductive barrel members spring-loading the probe members to partially and moveably extend beyond the conductive barrel members out of the housing in the pre-determined pattern.

8. The multi-contact probe assembly of claim 7 further comprising a plurality of probe connector members moveably disposed within the conductive barrel members, wherein the probe members are attached to the probe connector members and the spring members spring-load the probe connector members so that the probe members partially and moveably extend beyond the conductive barrel members out of the housing in the pre-determined pattern.

9. The multi-contact probe assembly of claim 8 wherein the plurality of electrical connectors are connected to the conductive barrel members.

10. The multi-contact probe assembly of claim 9 wherein at least one end of each conductive barrel member is crimped to at least one of prevent the probe connector members from extending beyond the conductive barrel members and to secure the electrical connectors in fixed positions relative to the conductive barrel members.

11. The multi-contact probe assembly of claim 1 further comprising at least one of a fastener and a fastener receptacle for attaching the housing to a circuit board.

12. A method of testing a circuit board comprising:
providing a multi-contact probe assembly comprising: a housing having a plurality of shafts in a pre-determined pattern; and a plurality of probe members moveably disposed partially within said shafts and biased to partially extend beyond the plurality of shafts out of the housing in said pre-determined pattern;
contacting a plurality of contacts on a circuit board with said plurality of probe members, wherein said plurality of contacts are in a substantially identical pattern as the pre-determined pattern; and
testing the circuit board using the probe members.

13. The method of claim 12 wherein the probe members are biased to partially extend beyond the plurality of shafts out of the housing with a plurality of spring members.

14. The method of claim 12 further comprising the steps of connecting, using at least one cable, a plurality of electrical connectors extending into the plurality of shafts to electrical testing equipment and communicating signals between the electrical testing equipment and the probe members.

15. The method of claim 12 wherein the pre-determined pattern comprises at least one of multiple rows of shafts, multiple rows of shafts comprising different numbers of shafts, and multiple rows of parallel shafts.

16. The method of claim 13 wherein the provided multi-contact probe assembly further comprises a plurality of conductive barrel members disposed within the plurality of shafts, wherein the plurality of spring members are disposed within the plurality of conductive barrel members spring-loading the probe members to partially and moveably extend beyond the conductive barrel members out of the housing in the pre-determined pattern.

17. The method of claim 16 wherein the provided multi-contact probe assembly further comprises a plurality of probe connector members moveably disposed within the conductive barrel members, wherein the probe members are attached to the probe connector members and the spring members spring-load the probe connector members so that the probe members partially and moveably extend beyond the conductive barrel members out of the housing in the pre-determined pattern.

18. The method of claim 17 wherein the provided multi-contact probe assembly further comprises a plurality of electrical connectors connected to the conductive barrel members.

19. The method of claim 18 wherein the provided multi-contact probe assembly has at least one end of each conductive barrel member crimped to at least one of prevent the probe connector members from extending beyond the conductive barrel members and to secure the electrical connectors in fixed positions relative to the conductive barrel members.

20. The method of claim 12 further comprising the step of attaching at least one fastener to a fastener receptacle of the multi-contact probe assembly to the circuit board.
